(19) United States
(12) Patent Application Publication
(10) Pub. No.: US 2007/0275530 A1
(43) Pub. Date: Nov. 29, 2007

(54) SEMICONDUCTOR STRUCTURE AND FABRICATING METHOD THEREOF

(76) Inventors: Wen-Han Hung, Kaohsiung City (TW); Cheng-Tung Huang, Kaohsiung City (TW); Da-Ching Chiou, Chiayi City (TW); Shyh-Fann Ting, Kaohsiung County (TW); Li-Shian Jeng, Taitung City (TW); Kun-Hsien Lee, Tainan City (TW); Tzermin Shen, Hsinchu City (TW); Tzyy-Ming Cheng, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,899

(22) Filed: May 24, 2006

(51) Int. Cl. H01L 21/336

(52) U.S. Cl. 438/299

(57) ABSTRACT

A semiconductor structure and a method of fabricating the same are provided. A substrate having a metal-oxide-semiconductor transistor is provided. The metal-oxide-semiconductor transistor includes a gate, a source/drain extended region, a first spacer, a liner, a source/drain and a metal silicide layer. A portion of the first spacer is removed to form a second spacer by performing an etching process. A contact etching stop layer is formed over the substrate.

### BACKGROUND OF THE INVENTION

1. Field of the Invention

The present invention relates to a semiconductor structure and fabricating method thereof. More particularly, the present invention relates to a semiconductor structure, wherein the stress inducing capability of a contact etching stop layer is increased for providing stress in a channel region, and a fabricating method thereof.

2. Description of the Related Art

In the development of the integrated circuit devices, the dimension of devices are miniaturized to achieve a higher operating speed and a lower power consumption. However, the miniaturization of device is often limited by factors such as fabrication yield and the production cost. Hence, there is a need to develop techniques different front the device miniaturizing techniques to improve the driving current of the device. To overcome the above limitation, some have proposed applying a stress to the channel region of a transistor. The application of stress to the channel may change the width in the silicon grid and increase the mobility of the electrons and holes. As a result, the performance of the device is improved.

At present, the stress necessary for increasing the performance of a device may be achieved using a silicon nitride layer to serve as a contact etching stop layer (CESL). FIG. 1 is a schematic cross-sectional view of a conventional semiconductor structure. The semiconductor structure 100 as shown in FIG. 1 includes a substrate 101 and a semiconductor device 120 disposed on the substrate 101. The semiconductor device 120 includes a gate structure 106, a source/drain extended region 108, a liner 110, a spacer 112, a source/drain region 114 and a metal silicide layer 116. The gate structure 106 is disposed on the substrate 101. Furthermore, the gate structure 106 includes a gate 104 disposed on the substrate 101 and a gate dielectric layer 102 disposed between the gate 104 and the substrate 101. The source/drain extended region 108 is disposed in the substrate 101 on both sides of the gate structure 106. The liner 110 is disposed on the sidewalls of the gate structure 106 and over the source/drain extended regions 108. The spacers 112 are disposed over the liner 110 on the respective sides of the gate structure 106. The source/drain region 114 is disposed in the substrate 101 beside the gate structure 106 and the spacers 112. The metal silicide layer 116 is disposed over the gate structure 106 and the source/drain regions 114. Furthermore, a contact etching stop layer 130 is disposed over the surface of the substrate 101 to cover the semiconductor devices 120.

In the semiconductor structure 100 shown in FIG. 1, the stress imparted by the contact etching stop layer 130 may be utilized to increase the mobility of electrons or holes in the channel region 118 between the source/drain extended regions 108. Thus, the driving current of the device is increased to effectively promote performance of the device.

However, because the spacer 112 is disposed between the contact etching stop layer 130 and the channel region 118, the contact etching stop layer 130 may not provide sufficient stress on the channel region 118. Hence, the performance of the semiconductor device 120 could hardly improve.

On the other hand, if the thickness of the contact etching stop layer 130 is increased to increase the stress on the channel region 118, the thickness of the semiconductor device 120 will be correspondingly increased and subsequent fabrication process more difficult to implement. For example, because of the increase in the level of integration of devices, the semiconductor devices 120 are disposed very close to each other. Therefore, the contact etching stop layer 130 will have rather uneven thickness after the deposition process. FIG. 2 is a schematic cross-sectional view of another conventional semiconductor structure. After forming the contact etching stop layer 130 over the substrate 101 as shown in FIG. 2, the contact etching stop layer 130 over two adjacent semiconductor devices 120 will merge together (indicated by the block A) due to their extreme closeness. As a result, the thickness of the contact etching stop layer 130 in block A area will be greater than the contact etching stop layer 130 elsewhere. Hence, in a subsequent process of forming a contact, incomplete etching or over-etching problem may occur due to the thickness variation in the contact etching stop layer 130. Ultimately, the yield and reliability of the device are adversely affected.

### SUMMARY OF THE INVENTION

Accordingly, at least one objective of the present invention is to provide a method of fabricating a semiconductor structure, wherein the stress inducing capability of a contact etching stop layer is increased for providing stress to a channel region.

At least another objective of the present invention is to provide a semiconductor structure, wherein the mobility of electrons or holes in a channel region is effectively increased.

At least yet another objective of the present invention is to provide a semiconductor structure with comparatively better performance.

To achieve these and other advantages and in accordance with the purpose of the invention, as embodied and broadly described herein, the present invention provides a method of fabricating a semiconductor structure. First, a substrate having a metal-oxide-semiconductor transistor formed thereon is provided. The metal-oxide-semiconductor transistor includes a gate structure, a source/drain extended region, a first spacer, a liner, a source/drain region and a metal silicide layer. The gate structure is formed on the substrate. The source/drain extended region is formed in the substrate at two sides of the gate structure. The first spacer is formed on a part of the source/drain extended region at two side of the gate structure. The liner is formed between the first spacer and the gate structure and between the first spacer and the source/drain extended region. The source/drain region is formed in the substrate at two sides of the gate structure and the first spacer. The metal silicide layer is formed on the gate structure and the source/drain region. Next, a source/drain extended region is formed in the substrate on the respective sides of the gate structure. Thereafter, a liner is formed over the sidewalls of the gate structure and over the source/drain extended regions. A first spacer is formed on the respective sidewalls of the gate structure over the liner. Next, a source/drain region is formed in the substrate on the respective sides of the gate structure. A metal silicide layer is formed over the gate structure and the source/drain regions. Next, a portion of the first spacer is removed to form a second spacer by performing an etching process. Later, a contact etching stop layer is formed over the surface of the substrate.

According to one embodiment of the present invention, the second spacer has a width of about 300 Å to 600 Å, for example.

According to one embodiment of the present invention, the method of forming the source/drain extended region includes performing an ion implant process on the substrate using the gate structure as a mask, for example.

According to one embodiment of the present invention, the method of forming the source/drain region includes performing an ion implant process on the substrate using the gate structure and the first spacers as a mask, for example.

According to one embodiment of the present invention, the etching process includes a dry etching or a wet etching process, for example.

According to one embodiment of the present invention, the first spacer and the liner are comprised of different materials, for example. The first spacer may be comprised of silicon nitride, silicon oxide, silicon oxynitride or polymer material, for example. The liner may comprise silicon oxide or silicon nitride, or is an oxide/nitride/oxide composite layer, for example.

According to one embodiment of the present invention, the metal silicide layer may comprise tungsten silicide, titanium silicide, cobalt silicide, tantalum silicide, nickel silicide, platinum silicide or palladium silicide, for example. The method of forming the metal silicide layer includes performing a self-aligned silicide process, for example.

According to one embodiment of the present invention, the contact etching stop layer may comprise silicon nitride, silicon oxide, silicon oxynitride, silicon carbide, silicon oxy-carbide or silicon-carbon nitride, for example. The method of forming the contact etching stop layer includes performing a chemical vapor deposition process, for example.

The present invention also provides a semiconductor structure comprising a substrate, a gate structure, a liner, spacers, source/drain extended regions, source/drain regions and a contact etching stop layer. The gate structure is disposed on the substrate. The source/drain extended regions are disposed in the substrate on the respective sides of the gate structure. The liner is disposed on the sidewalls of the gate structure and over the source/drain extended regions. The spacers are disposed on the respective sidewalls of the gate structure over the liner. The width of the spacers is smaller than the width of the liner on the source/drain extended region. The source/drain regions are disposed in the substrate on the respective sides of the gate structure. The contact etching stop layer is disposed on the surface of the substrate.

According to an embodiment of the present invention, the spacer has a width of about 300 Å to 600 Å, for example. Furthermore, the spacers and the liner are comprised of different materials. The spacer may comprise silicon nitride, silicon oxide, silicon oxynitride or polymer material, for example. The liner may comprise silicon oxide or silicon nitride, or is an oxide/nitride/oxide composite layer, for example.

According to an embodiment of the present invention, the semiconductor structure may further include a metal silicide layer disposed over the gate structure and the source/drain regions. The metal silicide layer may comprise tungsten silicide, titanium silicide, cobalt silicide, tantalum silicide, nickel silicide, platinum silicide or palladium silicide, for example.

According to an embodiment of the present invention, the contact etching stop layer may comprise silicon nitride, silicon oxide, silicon oxynitride, silicon carbide, silicon oxy-carbide or silicon-carbon nitride, for example.

The present invention also provides an alternative semiconductor structure comprising a substrate, a gate structure, source/drain extended regions, source/drain regions, metal silicide layers, spacers and a contact etching stop layer. The gate structure is disposed on the substrate. The source/drain extended regions are disposed in the substrate on the respective sides of the gate structure. The source/drain regions are disposed in the substrate on the respective sides of the gate structure and located beside the source/drain extended regions. The metal silicide layers are disposed over the gate structure and the source/drain regions. The spacers are disposed on the respective sidewalls of the gate structure. Furthermore, there is a gap between the spacer and the metal silicide layer over the source/drain region. The contact etching stop layer is disposed on the surface of the substrate.

According to an embodiment of the present invention, the spacer has a width of about 300 Å to 600 Å, for example. The spacer may comprise silicon nitride, silicon oxide, polysilicon, silicon oxynitride or polymer material, for example.

According to an embodiment of the present invention, the semiconductor structure may further include a liner disposed between the gate structure and the spacers and between the spacer and the source/drain extended regions. The liner and the spacers are comprised of different materials, for example. Furthermore, the liner may comprise silicon oxide or silicon nitride, or is an oxide/nitride/oxide composite layer, for example.

According to an embodiment of the present invention, the metal silicide layer may comprise tungsten silicide, titanium silicide, cobalt silicide, tantalum silicide, nickel silicide, platinum silicide or palladium silicide, for example.

According to an embodiment of the present invention, the contact etching stop layer may comprise silicon nitride, silicon oxide, silicon oxynitride, silicon carbide, silicon oxy-carbide or silicon-carbon nitride, for example.

In the present invention, an etching process is performed to remove a portion of the spacers before forming the contact etching stop layer. Therefore, the stress provided by the contact etching stop layer on the channel region is increased. As a result, the mobility of electrons or holes in the channel region is increased.

In addition, reduction of the size of the spacers may also prevents the formation of an unevenly deposited contact etching stop layer that can lead to an incomplete etching or over-etching during the process of forming a contact.

Moreover, only a portion of the spacers instead of the entire spacers are removed. Besides saving time to remove the entire spacers, the partial removal of the spacers also avoids damaging the metal silicide layer due to its exposure to a prolonged etching process. On the other hand, if the spacer between the gate and the contact are absent altogether, a leakage current may occur leading to a short circuit of the device and thereby adversely affect the reliability of the device.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of a conventional semiconductor structure.

FIG. 2 is a schematic cross-sectional view of another conventional semiconductor structure.

FIGS. 3A through 3D are schematic cross-sectional views showing the steps for fabricating a semiconductor structure according to one embodiment of the present invention.

FIG. 4 is a graph showing the relationship between the width of the spacer according to the present invention and the simulated tensile stress data.

FIG. 5 is a graph showing the relation between the width of the spacer according to the present invention and the simulated compressive stress data.

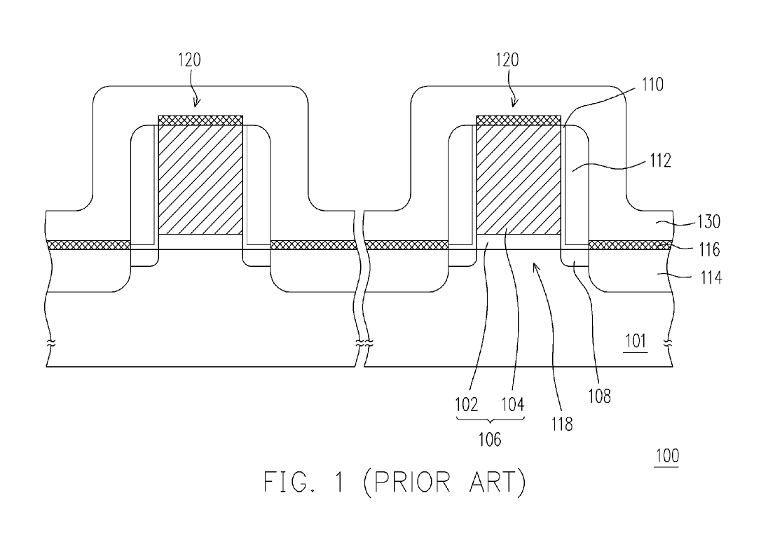

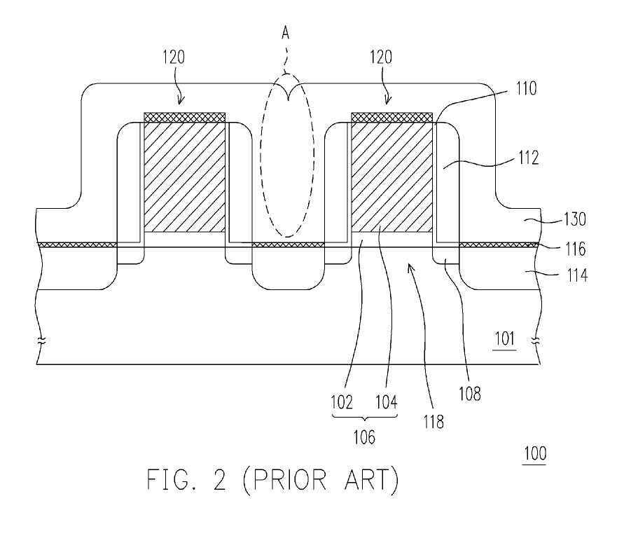

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

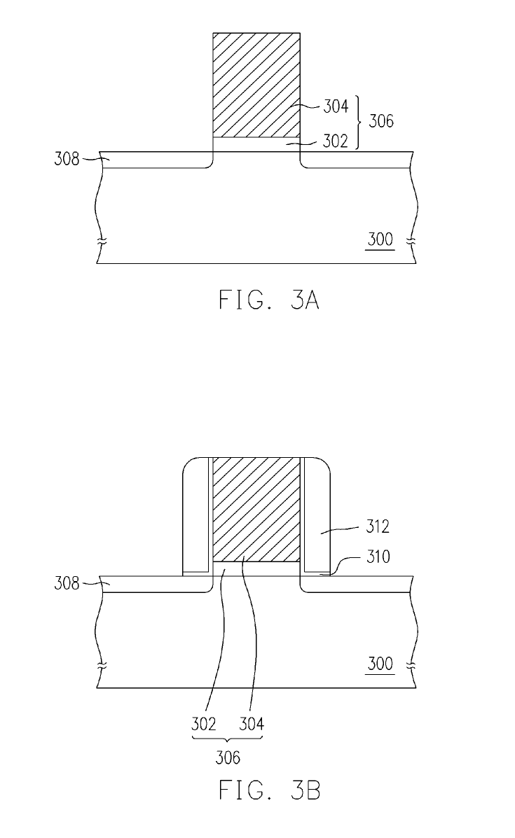

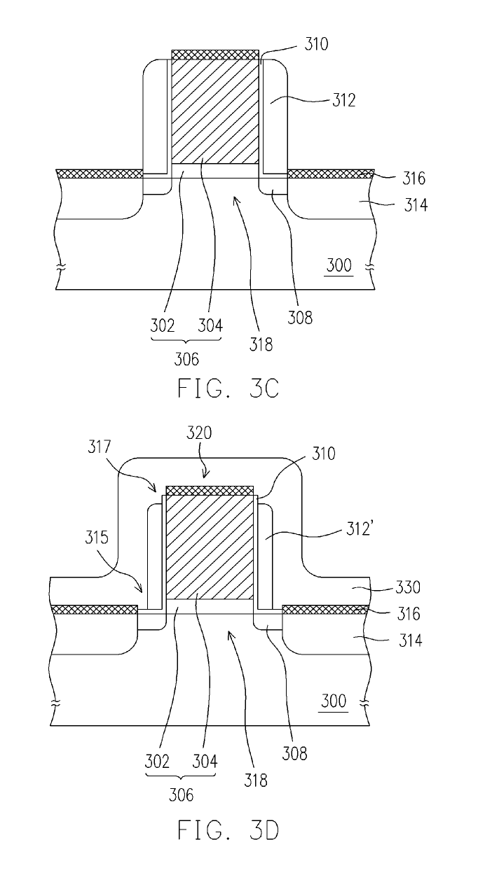

FIGS. 3A through 3D are schematic cross-sectional views showing the steps for fabricating a semiconductor structure according to one embodiment of the present invention. First, as shown in FIG. 3A, a substrate 300 is provided. Next, a gate structure 306 is formed over the substrate 300. The gate structure 306 includes a gate 304 over the substrate 300 and a gate dielectric layer 302 between the substrate 300 and the gate 304. Thereafter, a source/drain extended region 308 is formed in the substrate 300 on the respective sides of the gate structure 306. The method of forming the source/drain extended regions 308 includes, for example, performing an ion implantation on the substrate 300 using the gate structure 306 as a mask.

As shown in FIG. 3B, a liner material layer (not shown) is formed on the surface of the substrate 300. The liner material layer comprises silicon oxide or silicon nitride, for example. The method of forming the liner material layer includes performing a chemical vapor deposition process, for example. Furthermore, the liner material layer can also be an oxide/nitride/oxide composite layer. The composite liner material layer is fabricated, for example, by performing a thermal oxidation to form a silicon oxide layer over the substrate 300 and performing a chemical vapor deposition process to form a silicon nitride layer and a second silicon oxide layer in sequence over the silicon oxide layer. Thereafter, a spacer material layer (not shown) is formed over the liner material layer. The spacer material layer comprises silicon nitride, silicon oxide, silicon oxynitride or polymer material, for example. The method of forming the spacer material layer includes performing a chemical vapor deposition process, for example. More importantly, the spacer material layer and the liner material layer are comprised of different materials. This facilitates a subsequent process for removing portions of the spacers leaving the liner intact.

Again, as shown in FIG. 3B, an anisotropic etching operation is carried out to remove a portion of the spacer material layer to form spacers 312 on the sidewalls of the gate structure 306. Then, the liner material layer not covered by the spacers 312 is removed to form the liner 310 on the sidewalls of the gate structure 306 and over a portion of the source/drain extended regions 308.

As shown in FIG. 3C, a source/drain region 314 is formed in the substrate 300 beside the gate structure 306 and the spacers 312. The process of forming the source/drain regions 314 includes performing an ion implant process on the substrate 300 using the gate structure 312 and the spacers 312 as a mask. Thereafter, a metal silicide layer 316 is formed over the gate structure 306 and the source/drain regions 314 and a metal-oxide-semiconductor transistor formed. The metal silicide layer 316 comprises tungsten silicide, titanium silicide, cobalt silicide, tantalum silicide, nickel silicide, platinum silicide or palladium silicide, for example. The method of forming the metal silicide layer 316 includes performing a self-aligned silicide process, for example.

As shown in FIG. 3D, a portion of the spacers 312 is removed to form spacers 312′. The spacers 312′ and the gate structure 306, the source/drain extended regions 308, the liner 310, the source/drain regions 314 and the metal silicide layer 316 together form a semiconductor structure 320. The method of removing a portion of the spacers 312 includes performing an etching process, for example. The etching process can be a dry etching or a wet etching process. The spacer 312′ has a width of about 300 Å to 600 Å, for example.

It should be noted that the width of the spacer 312′ is smaller than the width of the liner 310 on the source/drain extended region 308 after removal a portion of the spacers 312. Furthermore, the height of the spacer 312′ is also shorter than the height of the gate structure 306. Therefore, the stress of the subsequently deposited contact etching stop layer on the substrate 300 will increase so that the mobility of the electrons or holes in the channel region 318 between the source/drain extended region 308 may be increased. More importantly, only a portion of the spacer 312 instead of the entire spacer 312 is removed. This method not only saves considerable processing time, but also reduce the possibility of damage to the metal silicide layer 316 due to its exposure to a prolonged etching operation required to remove the entire spacer 312. Furthermore, if the gate structure 306 has no spacer protecting its flanks, a leakage current occurring between the conductive layer inside a subsequently formed contact opening and the gate structure 306 which may consequently short circuit of the semiconductor device 320 and thereby reduce reliability of the device.

As shown in FIG. 3D, a contact etching stop layer 330 is formed over the surface of the substrate 300 to cover the semiconductor device 320. The contact etching stop layer 330 comprises silicon nitride, silicon oxide, silicon oxynitride, silicon carbide, silicon oxy-carbide or silicon-carbon nitride, for example. The method of forming the contact etching stop layer 330 includes performing a chemical vapor deposition process, for example.

It should be noted that the reduction of the spacer 312 into a smaller-size spacer 312′ may prevent the possibility of formation of contact etching stop layer 330 with an uneven thickness. Therefore, incomplete etching or over-etching in a subsequent contact etching process may be avoided. Moreover, after reducing the size of the spacer 312, the contact etching stop layer 330 may impart higher stress on the channel region 318 and thereby promote the performance of the semiconductor device 320.

In the following, a detailed description of the semiconductor structure is provided with reference to FIG. 3D. Since the materials of various components in the semiconductor structure have been described in the aforementioned embodiment, they will not be repeated hereinafter.

As shown in FIG. 3D, a semiconductor device 320 is disposed on a substrate 300. The semiconductor device 320 includes a gate structure 306, source/drain extended regions 308, a liner 310, spacers 312′, source/drain regions 314 and metal silicide layers 316. The gate structure 306 is disposed on the substrate 300. The gate structure 306 comprises a gate 304 over the substrate 300 and a gate dielectric layer 302 disposed between the substrate 300 and the gate 304. The source/drain extended regions 308 are disposed in the substrate 300 on the respective sides of the gate structure 306.

The liner 310 is disposed on the sidewalls of the gate structure 306 and over the source/drain extended regions 308. The spacers 312′ are disposed on the respective sidewalls of the gate structure 306 above the liner 310. The width of the spacer 312′ is smaller than the width of the liner 310 above the source/drain extended regions 308. The spacer 312′ has a width of about 300 Å to 600 Å, for example. In other words, a gap 315 is formed between the spacer 312′ and the metal silicide layer 316 on the source/drain region 314 and a gap 317 is formed between the spacer 312′ and the metal silicide layer 316 on the gate structure 306.

The source/drain regions 314 are disposed in the substrate 300 beside the gate structure 306. The metal silicide layers 316 are disposed on the gate structure 306 and the source/drain regions 314.

The contact etching stop layer 330 is disposed on the surface of the substrate 300 to cover the semiconductor device 320. It should be noted that the contact etching stop layer 330 will provide a different stress on the channel region 318 if the semiconductor device 320 is a MOS transistor of a different conductive type because of the slightly different formation of the contact etching stop layer 330. For example, in one embodiment, when the semiconductor device 320 is an NMOS transistor, the contact etching stop layer 330 can induce a tensile stress in the channel region 318 for increasing the mobility of electrons in the channel region 318. In another embodiment, when the semiconductor device 320 is a PMOS transistor, the contact etching stop layer 330 can induce a compressive stress in the channel region 318 for increasing the mobility of holes in the channel region 318. Therefore, through the tensile stress or compressive stress induced by the contact etching stop layer 330, the overall performance of the semiconductor device 320 is effectively promoted. It should be noted that the smaller size of the spacer 312′ can increase the amount of stress in the channel region 318 induced by the contact etching stop layer 330 and result in an increase in the mobility of the electrons or holes within the channel region 318. As a result, the performance of the device is promoted. Furthermore, the smaller size of the spacer 312′ also facilitates the formation of a contact etching stop layer 330 with a more uniform thickness. The uniformity of the contact etching stop layer 330 can prevent an incomplete etching or over-etching in a subsequent contact etching process.

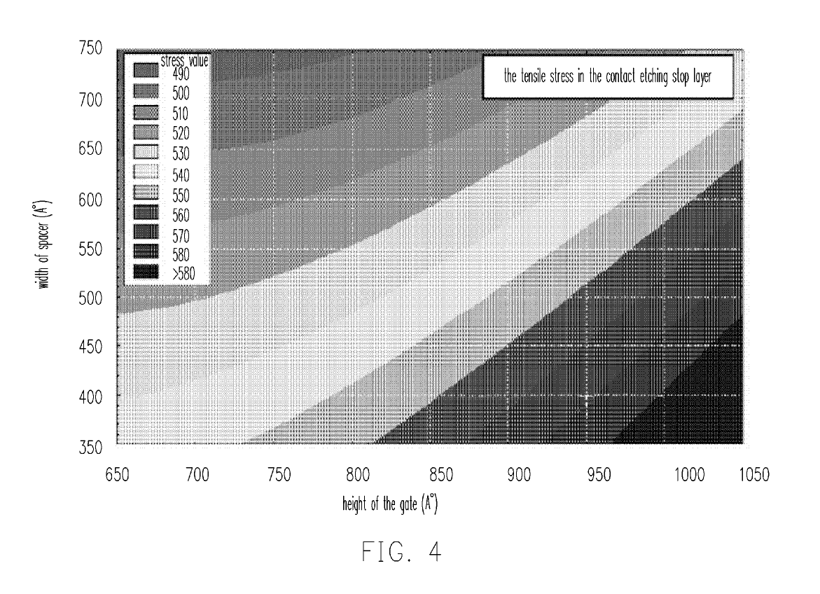

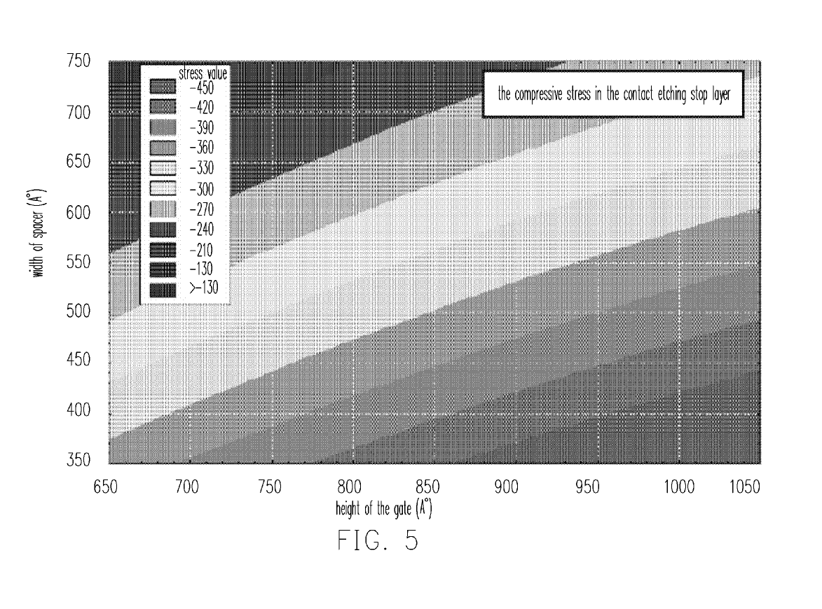

In the following, graphs showing the relationship between the width of the spacer and the simulated data of tensile stress and compressive stress is used to illustrate the effectiveness of the present invention. FIG. 4 is a graph showing the relationship between the width of the spacer according to the present invention and the simulated tensile stress data. FIG. 5 is a graph showing the relationship between the width of the spacer according to the present invention and the simulated compressive stress data. In FIGS. 4 and 5, a positive stress value represents a tensile stress while a negative stress value represents a compressive stress.

As shown in FIG. 4, the vertical axis represents the width of the spacer and the horizontal axis represents the height of the gate. In FIG. 4, the light-dark color region relates the aforementioned spacer width and gate height to the tensile stress induced by the contact etching stop layer. According to the graph, the smaller the width of the spacer, the greater will be the tensile stress produced by the contact etching stop layer.

Similarly, as shown in FIG. 5, the vertical axis represents the width of the spacer and the horizontal axis represents the height of the gate. In FIG. 5, the light-dark color region relates the aforementioned spacer width and gate height to the compressive stress induced by the contact etching stop layer. According to the graph, the smaller the width of the spacer, the greater will be the compressive stress produced by the contact etching stop layer.

In summary, according to the present invention, by reducing the size of the spacer, the stress induced by the contact etching stop layer may be increased. Hence, the mobility of the electrons or holes in the channel region is increased and the performance of the device is effectively promoted. The reduction in the size of the spacer also prevent the possibility of formation of a contact etching stop layer with an uneven thickness which would otherwise lead to an incomplete etching or over-etching during a subsequent contact etching process. Furthermore, since the size of the spacer is only trimmed down instead of removed completely, damage to the metal silicide layer due to its prolong exposure to the etching operation is minimized. Moreover, without completely removing the spacer, the chance of a leakage current occurring between the gate structure and the contact resulting in device short-circuit may be avoided. Thus, the reliability of the device is significantly promoted.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a semiconductor structure, comprising the steps of:
providing a substrate having a metal-oxide-semiconductor transistor formed thereon, and the metal-oxide-semiconductor transistor includes a gate structure formed on the substrate, a source/drain extended region formed in the substrate at two side of the gate structure, a first spacer formed on a part of the source/drain extended region at two side of the gate structure, a liner formed between the first spacer and the gate structure and between the first spacer and the source/drain extended region, a source/drain region formed in the substrate at two side of the gate structure and the first spacer and a metal silicide layer formed on the gate structure and the source/drain region;
performing an etching operation to remove a portion of the first spacers and form second spacers; and
forming a contact etching stop layer over the substrate.

2. The method of claim 1, wherein the second spacer has a width of about 300 Å to 600 Å.

3. The method of claim 1, wherein the step for forming the source/drain extended regions includes performing an ion implant process on the substrate using the gate structure as a mask.

4. The method of claim 1, wherein the step for forming the source/drain regions includes performing an ion implant process on the substrate using the gate structure and the first spacers as a mask.

5. The method of claim 1, wherein the etching process includes a dry etching or a wet etching operation.

6. The method of claim 1, wherein the first spacers and the liner are comprised of different materials.

7. The method of claim 6, wherein the first spacers comprise silicon nitride, silicon oxide, silicon oxynitride or polymer material.

8. The method of claim 6, wherein the liner comprises silicon nitride or silicon oxide or the liner is an oxide/nitride/oxide composite layer.

9. The method of claim 1, wherein the metal silicide layer comprises tungsten silicide, titanium silicide, cobalt silicide, tantalum silicide, nickel silicide, platinum silicide or palladium silicide.

10. The method of claim 1, wherein the step for forming the metal silicide layer includes performing a self-aligned silicide process.

11. The method of claim 1, wherein the contact etching stop layer comprises silicon nitride, silicon oxide, silicon oxynitride, silicon carbide, silicon oxy-carbide or silicon-carbon nitride.

12. The method of claim 1, wherein the step for forming the contact etching stop layer includes performing a chemical vapor deposition process.

13. A semiconductor structure, comprising:
a substrate;
a gate structure disposed on the substrate;
a source/drain extended region disposed in the substrate on each side of the gate structure;
a liner disposed on the sidewalls of the gate structure and over the source/drain extended region;
a spacer disposed on the sidewalls of the gate structure and over the liner, wherein the width of the spacer is smaller than the width of the liner above the source/drain extended regions;
a source/drain region disposed in the substrate on each side of the gate structure and the liner; and
a contact etching stop layer disposed on the surface of the substrate.

14. The semiconductor structure of claim 13, wherein the spacer has a width of about 300 Å to 600 Å.

15. The semiconductor structure of claim 13, wherein the spacers and the liner are comprised different materials.

16. The semiconductor structure of claim 15, wherein the spacers comprise silicon nitride, silicon oxide, silicon oxynitride or polymer material.

17. The semiconductor structure of claim 15, wherein the liner comprises silicon nitride or silicon oxide or the liner is an oxide/nitride/oxide composite layer.

18. The semiconductor structure of claim 13, further comprising a metal silicide layer disposed on the gate structure and the source/drain regions.

19. The semiconductor structure of claim 18, wherein the metal silicide layer comprises tungsten silicide, titanium silicide, cobalt silicide, tantalum silicide, nickel silicide, platinum silicide or palladium silicide.

20. The semiconductor structure of claim 13, wherein the contact etching stop layer comprises silicon nitride, silicon oxide, silicon oxynitride, silicon carbide, silicon oxy-carbide or silicon-carbon nitride.

21. A semiconductor structure, comprising:
a substrate;
a gate structure disposed on the substrate;
a source/drain extended region disposed in the substrate on each side of the gate structure;
a source/drain region disposed in the substrate on each side of the gate structure beside the source/drain extended region;
a metal silicide layer disposed on the gate structure and the source/drain regions;
a spacer disposed on the sidewalls of the gate structure such that a gap is formed between the spacer and the metal silicide layer on the source/drain region; and
a contact etching stop layer disposed on the surface of the substrate.

22. The semiconductor structure of claim 21, wherein the spacer has a width of about 300 Å to 600 Å.

23. The semiconductor structure of claim 21, wherein the spacers comprise silicon nitride, silicon oxide, silicon oxynitride or polymer material.

24. The semiconductor structure of claim 21, further comprising a liner disposed between the gate structure and the spacer, and between the spacer and the source/drain extended region.

25. The semiconductor structure of claim 24, wherein the liner and the spacer are comprised of different materials.

26. The semiconductor structure of claim 21, wherein the liner comprises silicon nitride or silicon oxide or the liner is an oxide/nitride/oxide composite layer.

27. The semiconductor structure of claim 21, wherein the metal silicide layer comprises tungsten silicide, titanium silicide, cobalt silicide, tantalum silicide, nickel silicide, platinum silicide or palladium silicide.

28. The semiconductor structure of claim 21, wherein the contact etching stop layer comprises silicon nitride, silicon oxide, silicon oxynitride, silicon carbide, silicon oxy-carbide or silicon-carbon nitride.
